(19) United States
(12) Patent Application Publication
(10) Pub. No.: US 2017/0323780 A1
(43) Pub. Date: Nov. 9, 2017

(54) THERMALLY CONDUCTIVE SHEET AND ELECTRONIC APPARATUS

(71) Applicant: JNC CORPORATION, TOKYO (JP)

(72) Inventors: SHIN KOGA, CHIBA (JP); TAKESHI FUJIWARA, CHIBA (JP); YASUHIRO SHIRAISHI, CHIBA (JP)

(73) Assignee: JNC CORPORATION, TOKYO (JP)

(21) Appl. No.: 15/524,269

(22) PCT Filed: Nov. 4, 2015
(86) PCT No.: PCT/JP2015/081078

§ 371 Date: May 4, 2017

(30) Foreign Application Priority Data
Nov. 5, 2014 (JP) 2014-225537

(51) Int. Cl. H01L 21/02; C09D 131/04; B32B 9/00; C08F 16/12; C08F 16/06; C08F 20/04

(52) U.S. Cl. CPC H01L 21/02118; C09D 131/04; B32B 9/007; C08F 16/06; C08F 20/04; C08F 16/12

(57) ABSTRACT

A thermally conductive sheet includes: a first graphite sheet; a second graphite sheet that is any of a second graphite sheet disposed to entirely overlap the first graphite sheet, a second graphite sheet disposed to partially overlap and to be shifted from the first graphite sheet, and a second graphite sheet disposed such that there is an interval of less than 5 mm between the second graphite sheet and the first graphite sheet; a first adhesive layer configured to adhere facing surfaces of the first graphite sheet and the second graphite sheet which are disposed; metal layers stacked to sandwich the first graphite sheet and the second graphite sheet which are disposed from the top and bottom; and second adhesive layers configured to adhere facing surfaces of the first graphite sheet, the second graphite sheet, and the metal layers which are disposed.

### TECHNICAL FIELD

The present invention relates to a thermally conductive sheet and an electronic apparatus using the same, and particularly relates to a thermally conductive sheet constituted of a plurality of graphite sheets.

### BACKGROUND ART

Graphite sheets are obtained by processing graphite serving as an allotrope of carbon, that is, black lead, to have a sheet shape. One of characteristics of graphite is the magnitude of thermal conductivity and the magnitude thereof is next to diamond and exceeds gold, silver, copper, and the like. Since graphite has such excellent thermal conductivity, graphite has been widely used as a thermal conductor.

In recent years, since the amount of heat generated by electronic apparatuses has increased along with increase in performance and increase in functionality, it has become necessary for the devices to use thermal conductors with excellent heat dissipation characteristics. Using a stacked body obtained by adhering a graphite sheet and a metal plate using an adhesive as such a thermal conductor is disclosed (Patent Literature 1).

However, since graphite sheets are obtained by removing hydrogen, oxygen, and nitrogen from specific polymer (polyimide and the like) sheets through strong heat treatment and annealing the remaining carbon atoms, when such polymer sheets serving as raw materials are thick, it is difficult to remove hydrogen, oxygen, and nitrogen gas generated in the inside thereof outside of the sheets through strong heat treatment and thus it is difficult to manufacture thick and highly dense graphite sheets. Furthermore, in the case of graphite sheets, there is a limit in sizes (areas) of commercially available sheets due to the above manufacturing method.

### CITATION LIST

### Patent Literature

### [Patent Literature 1]

Japanese Unexamined Patent Application Publication No. 2013-157599

### SUMMARY OF INVENTION

### Technical Problem

The present invention was made in view of the above-described circumstances and an objective of the present invention is to provide a thermally conductive sheet with excellent thermal conductivity in which heat is efficiently transferred between graphite sheets to obtain a thermally conductive sheet constituted of a plurality of graphite sheets. A plurality of graphite sheets are used so that a thicker or larger area thermally conductive sheet can be obtained.

### Solution to Problem

The present inventors found that heat can be efficiently transferred between a plurality of graphite sheets by appropriately disposing the graphite sheets and using an appropriate adhesive layer between the graphite sheets as a result of conducting intensive research to accomplish the above-described objective and completed the present invention.

For example, as shown in FIG. 1, a thermally conductive sheet according to a first aspect of the present invention is a thermally conductive sheet constituted of a plurality of graphite sheets and includes a first graphite sheet (4a); a second graphite sheet that is any of a second graphite sheet disposed to entirely overlap the first graphite sheet, a second graphite sheet (4a′) disposed to partially overlap and to be shifted from the first graphite sheet, and a second graphite sheet disposed such that there is an interval of less than 5 mm between the second graphite sheet and the first graphite sheet; a first adhesive layer (3a) configured to adhere facing surfaces (when the first and second graphite sheets overlap) of the first graphite sheet (4a) and the second graphite sheet (4a′) which are disposed; metal layers (2) stacked to sandwich the first graphite sheet (4a) and the second graphite sheet (4a′) which are disposed from the top and bottom; and second adhesive layers (3b) configured to adhere facing surfaces of the first graphite sheet (4a), the second graphite sheet (4a′), and the metal layers (2) which are disposed.

With such a configuration, when the first graphite sheet and the second graphite sheet are disposed to entirely or partially overlap, heat can be transferred in a stacked direction of the graphite sheets. When the first graphite sheet and the second graphite sheet are disposed with an interval therebetween, heat coming through the graphite sheet temporarily passes through the metal layer and returns to the graphite sheet again so that the heat can be transferred between the graphite sheets. Thus, a thermally conductive sheet with excellent thermal conductivity can be constituted using a plurality of graphite sheets. In addition, even when heat inside a heated body is non-uniform, heat can be transferred to be more rapidly uniformized when a thickness of a graphite sheet is thicker and heat can be transferred to be more widely uniformized when an area of a graphite sheet is larger.

According to a thermally conductive sheet according to a second aspect of the present invention, in the thermally conductive sheet according to the first aspect of the present invention, the first adhesive layer (3a) may include a polyvinyl acetal resin or an acrylic resin and the second adhesive layer (3b) may include a polyvinyl acetal resin.

With such a configuration, when the first graphite sheet and the second graphite sheet are disposed to entirely or partially overlap, since the adhesive layer (3a) can be formed to be very thin and thus thermal resistance can be decreased, heat can be efficiently transferred in a stacked direction of the graphite sheets. When the first graphite sheet and the second graphite sheet are disposed at intervals, since the adhesive layer (3b) can be formed to be very thin and thus thermal resistance can be decreased, heat coming through the graphite sheet temporarily passes through the metal layer and returns to the graphite sheet again so that heat can be efficiently transferred between the graphite sheets.

Also, a polyvinyl acetal resin is desirable because it has excellent toughness, heat-resisting properties, and impact resistance and has excellent adhesiveness even when a thickness thereof is thin.

According to a thermally conductive sheet according to a third aspect of the present invention, in the thermally conductive sheet according to the first aspect of the present invention, the first adhesive layer (3a) may include a polyvinyl acetal resin and the second adhesive layer (3b) may include an acrylic resin.

With such a configuration, when the first graphite sheet and the second graphite sheet are disposed to entirely or partially overlap, since the adhesive layer (3a) can be formed to be very thin and thus thermal resistance can be decreased, heat can be efficiently transferred in a stacked direction of the graphite sheets. When the first graphite sheet and the second graphite sheet are disposed at intervals, since the adhesive layer (3b) can be formed to be very thin and thus thermal resistance can be decreased, heat coming through the graphite sheet temporarily passes through the metal layer and returns to the graphite sheet again so that heat can be efficiently transferred between the graphite sheets.

Also, a polyvinyl acetal resin is desirable because it has excellent toughness, heat-resisting properties, and impact resistance and has excellent adhesiveness even when a thickness thereof is thin.

According to a thermally conductive sheet according to a fourth aspect of the present invention, for example, as shown in FIG. 2, in any one of the first to third aspects of the present invention, the thermally conductive sheet further includes: a third graphite sheet (4a″) disposed to partially overlap the first graphite sheet (4a) and the second graphite sheet (4a′) which are disposed to have an interval of less than 5 mm therefrom, wherein facing surfaces of the first graphite sheet (4a) and the third graphite sheet (4a″) may be adhered with the first adhesive layer (3a) and facing surfaces of the second graphite sheet (4a′) and the third graphite sheet (4a″) with the first adhesive layer (3a).

With such a configuration, since the adhesive layer (3a) can be formed to be very thin and thus thermal resistance can be decreased, for example, heat coming through the first graphite sheet temporarily passes through the third graphite sheet and transfers to the second graphite sheet so that heat can be efficiently transferred between the graphite sheets.

According to a thermally conductive sheet according to a fifth aspect of the present invention, in the thermally conductive sheet according to any one of the second to fourth aspects of the present invention, a polyvinyl acetal resin may include the following constituent units A, B, and C and in the constituent unit A, R is independently hydrogen or an alkyl group with 1 to 5 carbon atoms.

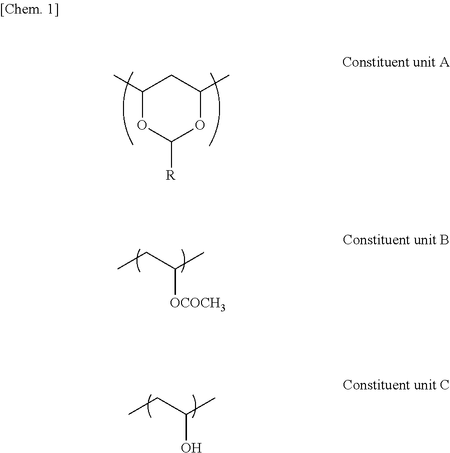

With such a configuration, the adhesive layers (3a and 3b) with excellent chemical resistance, flexibility, abrasion resistance, mechanical strength, solubility in a solvent, and adhesiveness can be obtained.

According to a thermally conductive sheet according to a sixth aspect of the present invention, in the thermally conductive sheet according to the fifth aspect of the present invention, a polyvinyl acetal resin may further include the following constituent unit D and in the constituent unit D, R¹ is independently hydrogen or an alkyl group with 1 to 5 carbon atoms.

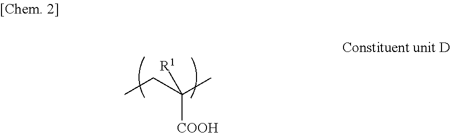

With such a configuration, the adhesive layers (3a and 3b) with more excellent adhesiveness can be obtained.

According to a thermally conductive sheet according to a seventh aspect of the present invention, in the thermally conductive sheet according to any one of the first to sixth aspects of the present invention, the adhesive layers (3a and 3b) may further include a thermally conductive filler.

With such a configuration, thermal conductivity of the adhesive layers (3a and 3b) can be improved.

According to a thermally conductive sheet according to an eighth aspect of the present invention, in the thermally conductive sheet according to any one of the first to seventh aspects of the present invention, thicknesses of the first graphite sheet and the second graphite sheet may be 10 to 300 μm.

With such a configuration, a thickness of the entire thermally conductive sheet can be made thinner.

According to a thermally conductive sheet according to a ninth aspect of the present invention, in the thermally conductive sheet according to any one of the first to eighth aspects of the present invention, a thickness of the metal layer may be 0.01 to 10 times the thickness of the first graphite sheet or the second graphite sheet.

With such a configuration, a thermally conductive sheet with excellent heat dissipation characteristics and mechanical strength can be obtained.

According to a thermally conductive sheet according to a tenth aspect of the present invention, in the thermally conductive sheet according to any one of the first to ninth aspects of the present invention, the metal layer may include at least one type of metal selected from the group consisting of silver, copper, aluminum, nickel, and an alloy containing at least one metal of these.

With such a configuration, a thermally conductive sheet with particularly good thermal conductivity can be obtained.

For example, as shown in FIG. 5, an electronic apparatus according to an eleventh aspect of the present invention includes: the thermally conductive sheet (1) according to any one of the first to tenth aspects of the present invention; and an electronic device having a heating body (10), wherein the thermally conductive sheet (1) is disposed in the electronic device to be in contact with the heating body (10).

With such a configuration, heat generated in the heating body can be efficiently dissipated using the thermally conductive sheet.

A thermally conductive sheet according to a twelfth aspect of the present invention is a thermally conductive sheet constituted of a plurality of graphite sheets including: a first graphite sheet; a second graphite sheet that is any of a second graphite sheet disposed to entirely overlap the first graphite sheet, a second graphite sheet disposed to partially overlap and to be shift from the first graphite sheet, and a second graphite sheet disposed such that there is an interval of less than 5 mm between the second graphite sheet and the first graphite sheet; and a first adhesive layer configured to adhere facing surfaces of the first graphite sheet and the second graphite sheet which are disposed, wherein the first adhesive layer includes a polyvinyl acetal resin.

With such a configuration, the first adhesive layer includes a polyvinyl acetal resin. Thus, since the adhesive layer has excellent adhesiveness, can be formed to be very thin, and has low thermal resistance, a thermally conductive sheet with excellent thermal conductivity between graphite sheets can be constituted even when there are no metal layers. Furthermore, a thickness of the entire thermally conductive sheet can be made thinner than those of cases in which other materials are used for adhesive layers.

### Advantageous Effects of Invention

According to a thermally conductive sheet of the present invention, since heat is efficiently transferred between graphite sheets, a thicker or larger area thermally conductive sheet with excellent thermal conductivity can be constituted of a plurality of graphite sheets.

### BRIEF DESCRIPTION OF DRAWINGS

FIG. 1 is a schematic cross-section view showing a thermally conductive sheet 1 obtained by stacking parts of two graphite sheets 4a and 4a′.

FIG. 2 is a schematic cross-section view showing a thermally conductive sheet 1 obtained by stacking three graphite sheets 4a, 4a′, and 4a″.

FIG. 3 is a schematic cross-section view showing a thermally conductive sheet 1 obtained by disposing two graphite sheets 4a and 4a′ without a space therebetween.

FIG. 4 is a schematic cross-section view showing a thermally conductive sheet 1 obtained by disposing two graphite sheets 4a and 4a′ with an interval therebetween.

FIG. 5 is a schematic cross-section view illustrating an example of an electronic apparatus including a thermally conductive sheet 1.

FIG. 6 is a schematic diagram illustrating an example of a graphite sheet 4b with holes.

FIG. 7 is a schematic diagram illustrating an example of a graphite sheet 4c with slits.

FIG. 8 is a schematic cross-section view showing a thermally conductive sheet formed of a plurality of graphite sheets.

FIG. 9 is a schematic cross-section view illustrating an example of an electronic apparatus including a thermally conductive sheet 1.

FIG. 10 is a schematic cross-section view illustrating an example of an LED light including a heat dissipating member (a thermally conductive sheet 1).

FIG. 11 is a configuration diagram of a device used in <Evaluation of heat dissipation characteristics>.

### DESCRIPTION OF EMBODIMENTS

The present invention is based on Japanese Patent Application No. 2014-225537 filed Nov. 5, 2014 in Japan and the content thereof is incorporated therein as the content of the present invention. The present invention can be more completely understood on the basis of the following detailed description. Further scope for application of the present invention will be clarified through the following detailed description. However, the detailed description and specific examples include preferable embodiments of the present invention and are merely for the purpose of explanation. Various changes and modifications will be clear to those of ordinary skill in the art within the spirit and scope of the present invention from the detailed description. The applicant intends that any modifications or alternatives of all described embodiments which have not been implemented in the public realm and which are not included in the scope of the claims to be included in the claims of the invention under the doctrine of equivalents.

Hereinafter, embodiments of the present invention will be described with reference to the drawings. Note that parts which are identical or equivalent to each other are denoted with the same reference numerals in the drawings and the descriptions thereof will be omitted. Also, the present invention is not limited to the following embodiments.

### [Layer Configuration of Thermally Conductive Sheet]

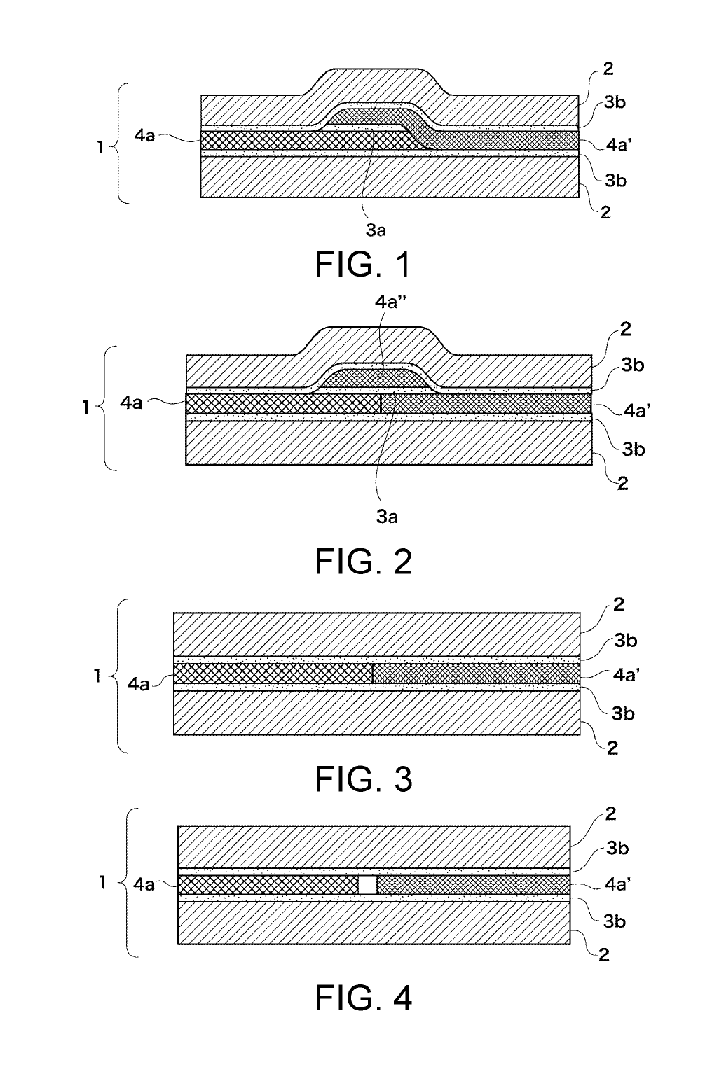

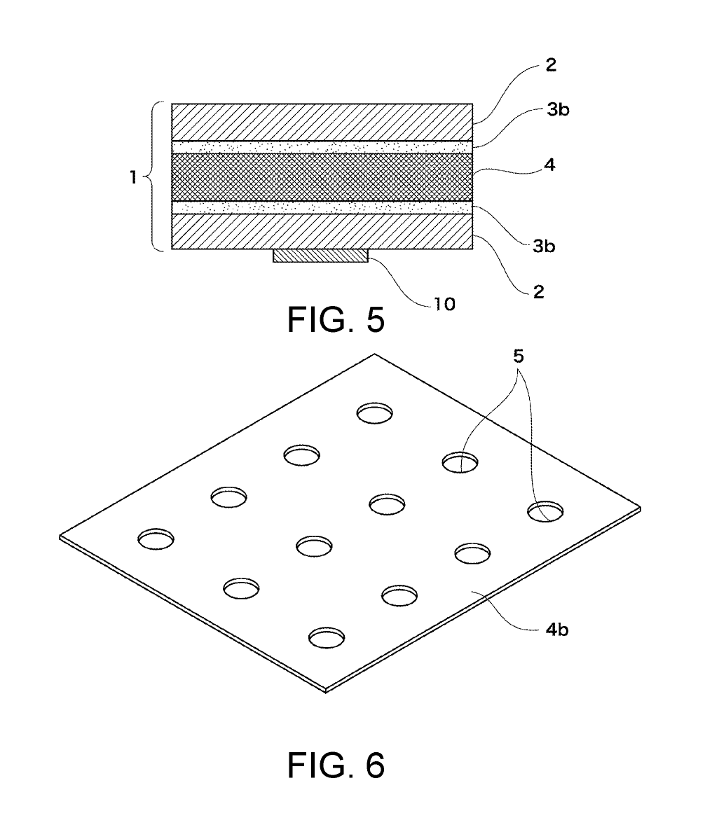

A thermally conductive sheet related to a first embodiment of the present invention is constituted of a graphite layer 4, metal layers 2 stacked to sandwich the graphite layer 4 from the top and bottom, and adhesive layers 3b configured to adhere the metal layers 2 to the graphite layer 4 as in, for example, a thermally conductive sheet 1 shown in FIG. 5. In the present invention, the graphite layer 4 may be constituted using a plurality of graphite sheets so that the thermally conductive sheet 1 with excellent thermal conductivity is realized. For example, layer configurations of a thermally conductive sheet 1 of the present invention are illustrated in FIGS. 1 to 4. However, the number of graphite sheets is not limited thereto. The number of graphite sheets of a thermally conductive sheet of the present invention may be appropriately determined in accordance with a thickness or an area required by a graphite layer.

FIG. 1 illustrates a thermally conductive sheet 1 including a first graphite sheet 4a, a second graphite sheet 4a′ disposed to partially overlap and be shifted from the first graphite sheet, a first adhesive layer 3a configured to adhere facing surfaces of the first graphite sheet 4a and the second graphite sheet 4a′, the metal layers 2 stacked to sandwich the first graphite sheet 4a and the second graphite sheet 4a′ from the top and bottom, and second adhesive layers 3b configured to adhere facing surfaces of the first graphite sheet 4a and the second graphite sheet 4a′, and the metal layers 2. Since an area of the graphite layer 4 can be increased in the layer configuration of FIG. 1, a thermally conductive sheet with a larger area can be obtained.

FIG. 2 illustrates a thermally conductive sheet 1 including a first graphite sheet 4a, a second graphite sheet 4a′ disposed to be arranged without there being a space between the second graphite sheet 4a′ and the first graphite sheet 4a, a third graphite sheet 4a″ disposed to partially overlap the first graphite sheet 4a and the second graphite sheet 4a′, a first adhesive layer 3a configured to adhere facing surfaces of the first graphite sheet 4a and the third graphite sheet 4a″ and adhere facing surfaces of the second graphite sheet 4a′ and the third graphite sheet 4a″, metal layers 2 stacked to sandwich the first to third graphite sheets 4a, 4a′, and 4a″ from the top and bottom, and second adhesive layers 3b configured to adhere facing surfaces of the first to third graphite sheets 4a, 4a′, and 4a″, and the metal layers 2. In a layer configuration of FIG. 2, heat can move between the first and second graphite sheets via the third graphite sheet and thus a thermally conductive sheet with a larger area can be obtained.

FIG. 3 illustrates a thermally conductive sheet 1 including a first graphite sheet 4a, a second graphite sheet 4a′ disposed to be arranged without there being a space between the second graphite sheet 4a′ and the first graphite sheet, metal layers 2 stacked to sandwich the first graphite sheet 4a and the second graphite sheet 4a′ from the top and bottom, and second adhesive layers 3b configured to adhere facing surfaces of the first and second graphite sheets 4a and 4a′ and the metal layers 2. Since an area of the graphite layer 4 can be increased in the layer configuration of FIG. 3, a thermally conductive sheet with a larger area can be obtained. Furthermore, since there is no overlapping of the graphite sheets, a surface of an outermost layer can be smoothened.

FIG. 4 illustrates a thermally conductive sheet 1 including a first graphite sheet 4a, a second graphite sheet 4a′ disposed such that there is an interval of less than 5 mm between the second graphite sheet 4a′ and the first graphite sheet, metal layers 2 stacked to sandwich the first graphite sheet 4a and the second graphite sheet 4a′ from the top and bottom, and second adhesive layers 3b configured to adhere facing surfaces of the first and second graphite sheets 4a and 4a′ and the metal layers 2. In the layer configuration of FIG. 4, a thermally conductive sheet with a larger area in which heat coming through one of the graphite sheets 4a temporarily passing through the metal layers 2 can move to the other of the graphite sheets 4a′ can be obtained. Furthermore, even when there is a slight gap (interval) between the graphite sheets, thermal conductivity does not decrease. Thus, a thermally conductive sheet is easily manufactured.

Note that, in FIGS. 3 and 4, an interval between the first graphite sheet and the second graphite sheet is 0 to less than 5 mm, preferably 0 to 3 mm, and particularly preferably 0 to 1 mm.

### [Graphite Sheets]

Graphite sheets constituting a graphite layer have high thermal conductivity and are sufficiently light and flexible. Such a plurality of graphite sheets are used so that a thermally conductive sheet with excellent heat dissipation characteristics as a heat dissipating member having a thicker graphite layer or a graphite layer with a larger area can be obtained.

A graphite sheet is not particularly limited as long as it is a sheet made of graphite, but for example, graphite sheets manufactured based on Japanese Unexamined Patent Application Publication No. S61-275117 and Japanese Unexamined patent Application Publication No. H11-21117 may be used and a commercial product may be used.

As commercial products, examples of an artificial graphite sheet (trade names) made of a synthetic resin sheet include eGRAF SPREADERSHIELD SS-1500 (manufactured by GrafTECH International), Graffinity (manufactured by Kaneka Co.), a PGS graphite sheet (manufactured by Panasonic Co.), and the like and examples of a natural graphite sheet (trade names) made of natural graphite include eGRAF SPREADERSHIELD SS-500 (manufactured by GrafTECH International) and the like.

A thermal conductivity of a graphite sheet in a direction which is substantially perpendicular to a stacked direction when the graphite sheet is stacked is preferably 250 to 2000 W/m-K, and more preferably 500 to 2000 W/m·K. As the thermal conductivity of the graphite sheet is within the above-described range, a thermally conductive sheet with excellent heat dissipation characteristics, thermal uniformity, and the like can be obtained.

A thermal conductivity of a graphite sheet in a direction which is substantially perpendicular to a stacked direction when the graphite sheet is stacked can be calculated by measuring a thermal diffusivity, a specific heat, and a density using a laser flash or xenon flash thermal diffusivity measurement device, DSC and an Archimedes method and multiplying the thermal diffusivity, the specific heat, and the density together.

A thickness of a graphite sheet is not particularly limited. In addition, in order to obtain a thermally conductive sheet which is thin and has excellent heat dissipation characteristics, the graphite sheet is preferably a thin layer, preferably of 1 to 600 μm, more preferably 5 to 500 μm, and particularly preferably 10 to 300 μm.

### [Metal Layer]

A surface of a metal layer which is in contact with an adhesive layer is preferably roughened.

A metal layer preferably has high thermal conductivity, is easily processed, is stable in working conditions of a thermally conductive sheet (hereinafter also referred to as a “heat dissipating member”), and has a foil or plate form which is easily obtained. Hereinafter, a metal plate, a metal foil, and the like are also all referred to as a “metal plate or the like.”

In order to obtain a thermally conductive sheet with sufficient thermal conductivity performance, a thermal conductivity of a metal layer is preferably 10 W/m·K and more preferably 70 to 500 W/m·K.

A metal layer is preferably a layer made of a metal selected such that the thermal conductivity of the metal layer is within the above-described range and is preferably a layer including at least one type of metal selected from the group consisting of silver, copper, aluminum, nickel, magnesium, titanium, and an alloy containing at least one of these metals such that a thermally conductive sheet with good thermal conductivity is obtained in the case of using the layer.

A layer including copper, aluminum, or nickel is desirable and a layer made of copper, aluminum, or nickel is more preferable in that copper, aluminum, or nickel are easily processed and obtained and stable in normal working conditions of a thermally conductive sheet, and a layer made of copper or aluminum is particularly preferable in that a metal plate or the like which has been subjected to surface roughening is easily prepared or obtained.

Also, a layer made of magnesium is desirable in that magnesium has a slightly lower thermal conductivity and a lower weight than those of aluminum. A layer made of titanium, for example, a titanium foil is desirable in that corrosion resistance thereof is significantly high and it is lightweight.

Examples of an alloy specifically include phosphor bronze, copper-nickel, duralumin, a magnesium alloy (AZ31), and the like.

As a metal layer, a surface of which has been roughened, a metal layer in which a metal plate or the like has been subjected to surface roughening with a conventionally known method may be used and a commercial product which has been roughened may be used.

Although a method of performing surface roughening on a metal layer is not particularly limited, for example, it can be appropriately selected or combined from means such as a method of assigning conditions such as a current value and roughening a commercially available metal plate or the like using an electric discharge machine and a method of processing or a method of grinding the metal plate or the like using a milling machine.

Note that, in a metal layer, at least a surface which is in contact with an adhesive layer may be roughened and a surface which is in contact with an adhesive layer and a surface opposite to the layer may be roughened.

A surface roughness of a roughened surface of a metal layer can be represented using the ten point mean roughness (Rz). In addition, Rz being 0.5 to 5.0 μm is desirable in that an adjustment or a metal plate or the like is satisfactorily obtained, Rz being 1.0 to 3.0 μm is more preferable in that a thermally conductive sheet with well-balanced and excellent adhesiveness and heat dissipation characteristics is obtained, and Rz being 1.5 to 3.0 μm is particularly preferable.

The surface roughness can be measured using, for example, a surface roughness measuring device, an atomic force microscope (AFM), and the like. To be specific, normally, the surface roughness can be measured on the basis of JIS B 0651. Note that the surface roughness may be measured using a light wave interference type surface roughness measuring instrument disclosed in JIS B 0652-1973.

A thickness of a metal layer is not particularly limited and may be appropriately selected in consideration of applications, a weight, a thermal conductivity, and the like of an obtained thermally conductive sheet, but it is preferably 5 to 1000 μm, more preferably 10 to 50 μm, and particularly preferably 12 to 40 μm in terms of ease of obtaining or the like. Furthermore, a thickness which is 0.01 to 100 times that of a graphite sheet is desirable and a thickness which is 0.1 to 10 times that of a graphite sheet is more preferable in that a thermally conductive sheet with excellent heat dissipation characteristics and mechanical strength can be obtained.

A thickness of a metal layer can be acquired by measuring a weight per a unit area thereof and by performing calculation using the measured weight and the specific gravity of a component such as a metal or the like forming the metal layer.

### [Adhesive Layer]

A first adhesive layer 3a is not particularly limited as long as the first adhesive layer 3a is a layer which can adhere graphite sheets and is preferably a layer obtained by applying a composition including a resin to graphite sheets and bonding the graphite sheets and drying and curing the composition according to necessity.

A second adhesive layer 3b is not particularly limited as long as the second adhesive layer 3b is a layer which can adhere a metal layer and a graphite sheet and is desirably a layer obtained by applying a composition including a resin to a metal layer or a graphite sheet and drying and curing the composition according to necessity.

Although a natural adhesive layer and a synthetic adhesive layer can both be used as an adhesive layer, a synthetic adhesive layer is desirable in that stable characteristics are obtained.

As a synthetic adhesive layer, a layer including one type or two types or more from acrylic resins, polyolefin resins, urethane resins, ether-based celluloses, ethylene vinyl acetate resins, epoxy resins, polyvinyl chloride, chloroprene rubber, polyvinyl acetate resins, polycyanoacrylates, silicone-based resins, styrene butadiene resins, polyvinyl acetal resins, nitrile rubber, nitrocellulose, phenol resins, polyamide resins, polyimide resins, polyvinyl alcohol, polyvinyl pyrrolidone, or resorcinol resins or a layer formed of a composition including one type or two types thereof is preferably used.

The first adhesive layer 3a is preferably a layer formed of a composition including a polyvinyl acetal resin in that can obtain a thermally conductive sheet with an excellent bonding strength between graphite sheets and bendable, and with excellent heat dissipation characteristics, toughness, flexibility, a heat-resisting property, impact resistance, and the like. And the second adhesive layer 3b is preferably a layer formed of a composition including a polyvinyl acetal resin in that can obtain a thermally conductive sheet with an excellent bonding strength between the metal layer and the graphite sheet and bendable, and with excellent heat dissipation characteristics, toughness, flexibility, a heat-resisting property, impact resistance, and the like can be obtained. The composition may further include an additive, a thermally conductive filler, a solvent, and the like within an extent that the effects of the present invention are not impaired in accordance with a type of metal layer or the like in addition to a polyvinyl acetal resin.

### [Polyvinyl Acetal Resin]

Although a polyvinyl acetal resin is not particularly limited, the polyvinyl acetal resin is preferably a resin including the following constituent units A, B, and C in that to obtain adhesive layers with excellent toughness, a heat-resisting property, and impact resistance, and with excellent adhesiveness between graphite sheets and between a metal layer and a graphite sheet even with a thin thickness.

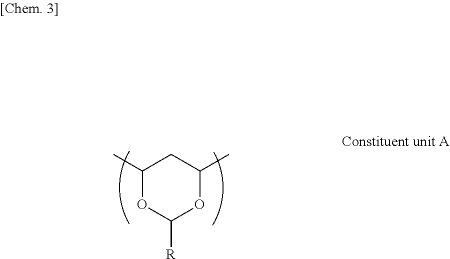

The constituent unit A is a constituent unit with an acetal site and may be formed, for example, through a reaction between a continuous polyvinyl alcohol chain unit and an aldehyde (R—CHO).

R in the constituent unit A is independently hydrogen or an alkyl group. When R is a bulky group (for example, a hydrocarbon group with many carbon atoms), a softening point of a polyvinyl acetal resin tends to be low. Furthermore, in a polyvinyl acetal resin in which R is a bulky group, a solubility in a solvent is higher but the chemical resistance thereof deteriorates in some cases. For this reason, R is preferably hydrogen or an alkyl group with 1 to 5 carbon atoms, is more preferably hydrogen or an alkyl group with 1 to 3 carbon atoms in terms of toughness or the like of an obtained adhesive layer, is more preferably hydrogen or a propyl group, and is particularly preferably hydrogen in terms of a heat-resisting property or the like.

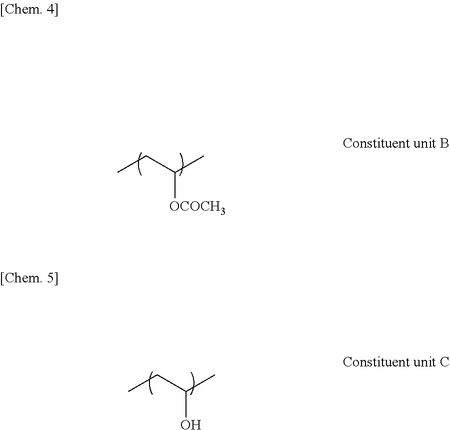

A polyvinyl acetal resin can include the following constituent unit D in addition to the constituent units A to C. R¹ in the constituent unit D is independently hydrogen or an alkyl group with 1 to 5 carbon atoms, preferably hydrogen or an alkyl group with 1 to 3 carbon atoms, and more preferably hydrogen.

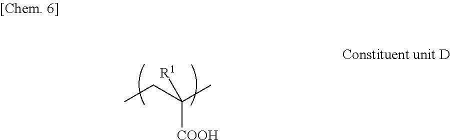

A total content of the constituent units A, B, C, and D in a polyvinyl acetal resin is preferably 80 to 100 mol % with respect to all constituent units of the resin.

The constituent units A to D may be randomly arranged (a random copolymer), and although they may be arranged with regularity in a polyvinyl acetal resin (a block copolymer, an alternating copolymer, and the like), the constituent units A to D are preferably randomly arranged.

In constituent units in a polyvinyl acetal resin, a content of the constituent unit A with respect to all constituent units of the resin is preferably 49.9 to 80 mol %, a content of the constituent unit B is preferably 0.1 to 49.9 mol %, a content of the constituent unit C is 0.1 to 49.9 mol %, and a content of the constituent unit D is preferably 0 to 49.9 mol %. More preferably, a content of the constituent unit A with respect to all constituent units of a polyvinyl acetal resin is 49.9 to 80 mol %, a content of the constituent unit B is 1 to 30 mol %, a content of the constituent unit C is 1 to 30 mol %, and a content of the constituent unit D is 1 to 30 mol %.

A content of the constituent unit A is preferably 49.9 mol % or more in that a polyvinyl acetal resin with excellent chemical resistance, flexibility, abrasion resistance, and mechanical strength is obtained.

Since the solubility of a polyvinyl acetal resin in a solvent is improved when a content of the constituent unit B is 0.1 mol % or more, this content thereof is desirable. Furthermore, since chemical resistance, flexibility, abrasion resistance, and mechanical strength of a polyvinyl acetal resin hardly decrease when a content of the constituent unit B is 49.9 mol % or less, this content thereof is desirable.

A content of the constituent unit C is preferably 49.9 mol % or less in terms of the solubility of a polyvinyl acetal resin in a solvent, obtained adhesiveness of an adhesive layer with a metal layer or a graphite sheet, and the like. Furthermore, since the constituent unit B and the constituent unit C have an equilibrium relationship when a polyvinyl alcohol chain is acetalized in manufacturing a polyvinyl acetal resin, a content of the constituent unit C is preferably 0.1 mol % or more.

A content of the constituent unit D is preferably within the above-described range in that to obtain an adhesive layer has an excellent bonding strength between the metal layer and the graphite sheet.

The contents of constituent units A to C in a polyvinyl acetal resin can be measured in conformity to JIS K 6728 or JIS K 6729,

A content of a constituent unit D in a polyvinyl acetal resin can be measured using the following method.

A polyvinyl acetal resin is heated to 80° C. in a 1 mol/l aqueous sodium hydroxide solution for two hours. Through such an operation, sodium is added to a carboxyl group and a polymer including —COONa is obtained. After excess sodium hydroxide is extracted from the polymer, the polymer is dried by evaporation. After that, the polymer is carbonized and is subject to atomic absorption analysis. In addition, an amount of addition of sodium is obtained and quantified.

Note that, when a content of a constituent unit B (a vinyl acetate chain) is determined, a constituent unit D is quantified as a vinyl acetate chain. Thus, a content of the quantified constituent unit D is subtracted from the content of the constituent unit B measured in conformity to JIS K 6728 or JIS K6729 and thus the content of the constituent unit B is corrected.

A weight average molecular weight of a polyvinyl acetal resin is preferably 5000 to 300000 and more preferably 10000 to 150000. Since a thermally conductive sheet can be easily manufactured and a thermally conductive sheet with excellent molding processability and bending strength is obtained when a polyvinyl acetal resin, a weight average molecular weight of which is within the above-described range, is used, this weight average molecular weight thereof is desirable.

In the present invention, a weight average molecular weight of a polyvinyl acetal resin can be measured using a gel permeation chromatography (GPC) method. Specific measurement conditions are as follows.

Detector: 830-RI (manufactured by JASCO Co., Ltd.)

Oven: NFL-700M (manufactured by Nishio KogyoKabushiki Kaisha)

Separation column: Two Shodex KF-805L

Pump: PU-980 (manufactured by JASCO Co., Ltd.)

Temperature: 30° C.

Carrier: tetrahydrofuran

Standard sample: polystyrene

An Ostwald viscosity of a polyvinyl acetal resin is preferably 1 to 100 mPa·s. Since a thermally conductive sheet can be easily manufactured and a thermally conductive sheet with excellent toughness is obtained when a polyvinyl acetal resin, the Ostwald viscosity of which is within the above-described range, is used, the polyvinyl acetal resin is desirable.

The Ostwald viscosity can be measured at 20° C. using a solution obtained by dissolving 5 g of a polyvinyl acetal resin in 100 ml of dichloroethane and an Ostwald-Cannon Fenske Viscometer.

Specific examples of a polyvinyl acetal resin include polyvinyl butyral, polyvinyl formal, polyvinyl acetoacetal, derivatives thereof, and the like and polyvinyl formal is desirable in terms of adhesiveness with a graphite sheet, a heat-resisting property of an adhesive layer, and the like.

As a polyvinyl acetal resin, the above-described resins may be independently used and a combination of two or more types of resin in which a bonding order or the number of bonds of constituent units is different may be used.

A polyvinyl acetal resin may be obtained through synthesis and may be a commercial product.

Although a method of synthesizing a resin including constituent units A, B, and C is not particularly limited, for example, the method disclosed in Japanese Unexamined Patent Application Publication No. 2009-298833 can be included. Furthermore, although a method of synthesizing a resin including constituent units A, B, C, and D is not particularly limited, for example, the method disclosed in Japanese Unexamined Patent Application Publication No. 2010-202862 can be included.

As a commercial product of a polyvinyl acetal resin, Vinylec C, Vinylec K (trade name; manufactured by JNC Co., Ltd.), and the like are included as a polyvinyl formal and Denka Butyral 3000-K (trade name; manufactured by Denka Company Ltd.) and the like are included as a polyvinyl butyral.

### [Additives]

An additive such as a stabilizer and a modifier may be added to a composition including a polyvinyl acetal resin within a normally used range. As such an additive, a commercially available additive can be used. Furthermore, another resin can also be added to a composition including a polyvinyl acetal resin in a range in which characteristics of the polyvinyl acetal resin are not impaired.

These additives may be independently used and a combination of two or more types thereof may be used.

As an additive, for example, when a resin forming an adhesive layer deteriorates due to contact with a metal, addition of a copper inhibitor or a metal deactivator as described in Japanese Unexamined Patent Application Publication No. H5-48265 is desirable, and when a composition includes a thermally conductive filler, addition of a silane coupling agent is desirable to improve adhesion between the thermally conductive filler and a polyvinyl acetal resin, and addition of an epoxy resin is desirable to improve a heat-resisting property (a glass transition temperature) of an adhesive layer.

As a silane coupling agent, a silane coupling agent (trade name; S330, 5510, S520, and 5530) manufactured by JNC Co., Ltd. and the like is desirable.

An amount of addition of a silane coupling agent is preferably 1 to 10 parts by weight with respect to 100 parts by weight of the total resin included in an adhesive layer in that the silane coupling agent can improve adhesiveness with a metal layer.

As an epoxy resin (trade names), jER828, jER827, jER806, jER807, jER4004P, jER152, and jER154 manufactured by Mitsubishi Chemical Co., Ltd.; Celoxide 2021 P and Celoxide 3000 manufactured by Daicel Co., Ltd.; YH-434 manufactured by Nippon Steel Chemical Co., Ltd.; EPPN-201, EOCN-102S, EOCN-103S, EOCN-104S, EOCN-1020, EOCN-1025, EOCN-1027, DPPN-503, DPPN-502H, DPPN-501H, NC6000, and EPPN-202 manufactured by Nippon Kayaku Co., Ltd.; DD-503 manufactured by ADEKA Co., Ltd.; and RIKARESIN W-100 manufactured by New Japan Chemical Co., Ltd. and the like are desirable.

An amount of addition of an epoxy resin is preferably 1 to 49% by weight with respect to 100% by weight of the total resin included in an adhesive layer in that a glass transition temperature of the adhesive layer can be increased.

When an epoxy resin is added, it is desirable to further add a curing agent. As the curing agent, an amine-based curing agent, a phenol-based curing agent, a phenol novolac-based curing agent, an imidazole-based curing agent, and the like are desirable.

When a thermally conductive sheet is used in a high temperature and high humidity environment or the like, a copper inhibitor or a metal deactivator may be added to an adhesive layer.

Although a polyvinyl acetal resin is used for enameled wires and the like in the related art and is a resin which hardly degrades due to contact with a metal or degrades a metal, a copper inhibitor or a metal deactivator may be added when a thermally conductive sheet is used in a high temperature and high humidity environment or the like.

As a copper inhibitor (trade names), Mark ZS-27 and Mark CDA-16 manufactured by ADEKA Co., Ltd.; SANKO-EPOCLEAN manufactured by Sanko Chemical Industry Co., Ltd.; Irganox MD1024 manufactured by BASF Company, and the like are desirable.

An amount of addition of a copper inhibitor is preferably 0.1 to 3 parts by weight with respect to 100 parts by weight of the total resin included in an adhesive layer in that deterioration of a resin of a portion which comes into contact with a metal of the adhesive layer can be prevented.

### [Thermally Conductive Filler]

Although first and second adhesive layers may include a small amount of thermally conductive fillers for the purpose of improving thermal conductivity, since addition of a thermally conductive filler tends to decrease adhesive performance and to increase a thickness of an adhesive layer, it is necessary to pay attention to a balance between an amount of addition, and adhesive performance or a particle size when the thermally conductive filler is added. Furthermore, addition of a thermally conductive filler promotes forming of voids (gaps) depending on a shape of a roughened surface of a metal layer in some cases. Thus, it is necessary to pay attention to this when a filler is used.

Examples of a thermally conductive filler include, but are not particularly limited to, a metal as a metallic powder, a metal oxide powder, a metal nitride powder, a metal hydroxide powder, a metal oxynitride powder, a powder including a carbon material such as a metal carbide powder, or a filler including metal compound, and a filler including a carbon material, and the like.

These thermally conductive fillers may be independently used and a combination of two or more types thereof may be used.

A commercial product, an average diameter and a shape of which are within a desired range, may be directly used as a thermally conductive filler and a commercial product which has been subjected to grinding, grading, heating, or the like so that an average diameter and a shape thereof are within a desired range may be used as the thermally conductive filler.

Note that, although an average diameter and a shape of a thermally conductive filler may change in a process of manufacturing the thermally conductive sheet of the present invention in some cases, it is desirable that an aspect in which a filler with the average diameter and the shape is blended with a composition including a polyvinyl acetal resin is used.

A desirable amount of the thermally conductive filler blended in is 1 to 20% by weight with respect to 100% by weight of the composition.

### [Solvent]

A solvent is not particularly limited as long as the solvent can dissolve a polyvinyl acetal resin and is preferably a solvent which can disperse a thermally conductive filler. In addition, examples of the solvent include an alcohol-based solvent such as methanol, ethanol, n-propanol, iso-propanol, n-butanol, sec-butanol, n-octanol, diacetone alcohol, and benzyl alcohol; a cellosolve-based solvent such as methyl cellosolve, ethyl cellosolve, and butyl cellosolve; a ketone-based solvent such as acetone, methyl ethyl ketone, cyclopentanone, cyclohexanone, and isophorone; an amide-based solvent such as N,N-dimethylacetamide, N,N-dimethylformamide, and 1-methyl-2-pyrrolidone; an ester-based solvent such as methyl acetate and ethyl acetate; an ether-based solvent such as dioxane and tetrahydrofuran; a chlorinated hydrocarbon-based solvent such as methylene chloride and chloroform; an aromatic-based solvent such as toluene and pyridine; dimethylsulfoxide; acetic acid; terpineol; butyl carbitol; butyl carbitol acetate, and the like.

These solvents may be independently used and a combination of two or more types thereof may be used.

A solvent is used in an amount in which a resin concentration in a composition including a polyvinyl acetal resin is preferably 3 to 30% by weight and more preferably 5 to 20% by weight and this is desirable in terms of manufacturability, heat dissipation characteristics, and the like of a thermally conductive sheet.

### [Physical Properties of Adhesive Layer and the Like]

The thermal conductivity of an adhesive layer in a stacked direction when the adhesive layer has been stacked is preferably 0.05 to 50 W/m·K and more preferably 0.1 to 20 W/m·K. As the thermal conductivity of an adhesive layer is within the above-described range, a thermally conductive sheet with excellent heat dissipation characteristics and adhesiveness can be obtained.

When the thermal conductivity of an adhesive layer is an upper limit or less in the above-described range, the thermal conductivity thereof is desirable because an adhesive strength between a metal layer and a graphite sheet and an adhesive strength between graphite sheets increases and a thermally conductive sheet with an excellent mechanical strength and durability is obtained. On the other hand, when the thermal conductivity of an adhesive layer is a lower limit or more in the above-described range, the thermal conductivity thereof is desirable because a thermally conductive sheet with excellent heat dissipation characteristics is obtained.

The thermal conductivity of an adhesive layer in a stacked direction thereof can be calculated from a thermal diffusivity obtained from a laser flash or xenon flash thermal diffusivity measurement device, a specific heat obtained from differential scanning calorimetry (DSC), and a density obtained through an Archimedes method.

When thermally conductive sheets of the present invention each have metal layers, second adhesive layers 3b with a thickness which is substantially the same as the surface roughness (Rz) of the metal layer are provided. Thus, well-balanced excellent adhesiveness and thermal conductivity in a stacked direction are obtained. Since a surface roughness of a metal layer is preferably 0.5 to 5.0 μm and more preferably 1.0 to 3.0 μm, a thickness of the second adhesive layer 3b is preferably 0.5 to 5.0 μm and more preferably 1.0 to 3.0 μm.

A thickness of a first adhesive layer 3a adhering graphite sheets is preferably 0.05 to 20 μm, more preferably 0.05 to 5 μm, and further more preferably 0.05 to 2 μm.

A difference (t−Rz) obtained by subtracting a surface roughness (Rz) of a surface which is in contact with the adhesive layer of the metal layer from a thickness (t) of the second adhesive layer 3b is preferably −0.5 μm or more and less than 1.0 μm in that a thermally conductive sheet with well-balanced excellent adhesiveness and thermal conductivity is obtained. In addition, more preferably, an absolute value (|Rz−t|) of a difference between Rz and t is more preferably 0.5 μm or less and particularly preferably 0.2 μm or less in that a thermally conductive sheet with well-balanced excellent adhesiveness and thermal conductivity is obtained. Note that a lower limit of |Rz−t| may be 0 μm.

Also, it is desirable that Rz and t satisfy the above-described relationship and that Rz<t in that a thermally conductive sheet with particularly excellent adhesiveness is obtained.

When a relationship between a surface roughness (Rz) of a surface of a metal layer which comes into contact with an adhesive layer and a thickness (t) of the adhesive layer is within the above-described range, it can be said that a thickness of the adhesive layer is equal to a surface roughness of the metal layer.

When the difference (t−Rz) obtained by subtracting the surface roughness (Rz) of the surface which is in contact with the adhesive layer of the metal layer from the thickness (t) of the second adhesive layer is less than 0.5 the adhesive layer does not have a thickness in which the metal layer and a graphite sheet layer can be adhered and the obtained thermally conductive sheet tends to have a deteriorated bonding strength.

Examples of the first and second adhesive layers with thin thicknesses in the present invention include adhesive layers with thicknesses of 3 μm or less.

A thickness of an adhesive layer can be adjusted, for example, by variously changing conditions when a composition including a polyvinyl acetal resin is applied to a metal layer or a graphite sheet. Examples of changeable conditions include an application method, a solid concentration, a coating rate, and the like.

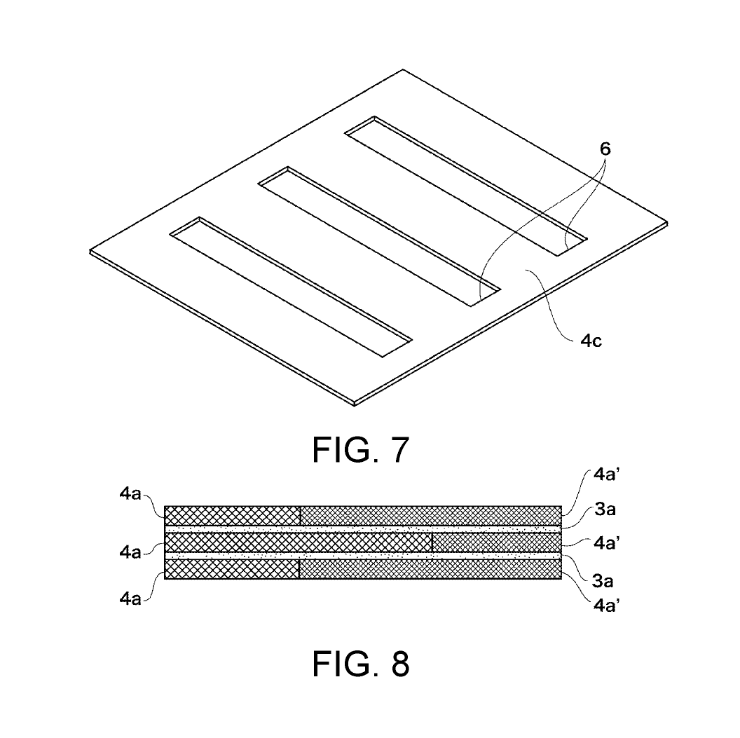

Note that a thickness of an adhesive layer is a thickness between a metal layer or a graphite sheet which is in contact with one side of one layer of an adhesive layer and a metal layer or a graphite sheet which is in contact with a surface opposite to the surface which is in contact with the metal layer or the graphite sheet of the adhesive layer. Here, even when the adhesive layers as shown in FIGS. 6 and 7 are used, the thickness thereof does not include a thickness of an adhesive layer with which holes 5 or slits 6 of the graphite sheets may be filled and is a thickness between the metal layers and/or the graphite sheets.

A thermally conductive filler which may be included in a metal or an adhesive layer pierces the graphite sheet in some cases. In addition, even in this case, a thickness of an adhesive layer is a thickness between the metal layers and/or the graphite sheets without considering the portion pierced into the graphite sheet.

A thickness of a second adhesive layer 3b is specifically a distance between a mean line and a graphite sheet when the mean line is drawn in a roughness curve formed in a surface of a metal layer which has been subjected to surface roughening.

A thickness of an adhesive layer can be specifically calculated using a difference between an average value of thicknesses of an uncoated part obtained by a film thickness meter (there is variation according to Rz depending on roughening) and an average value of thicknesses of an adhesive layer forming component coated part. An average thickness of an uncoated part is a distance from the mean line to a non-roughened end.

A thickness of an adhesive layer forming component coated part can be measured, for example, from a difference between a thickness of a metal layer with an adhesive layer formed thereon and a metal layer with no an adhesive layer formed thereon using a step meter.

### [Configuration and the Like of Thermally Conductive Sheet]

The thermally conductive sheets of the present invention are not particularly limited as long as the thermally conductive sheets include stacked bodies having metal layers, adhesive layers, and graphite layers formed of a plurality of graphite sheets. In addition, each of the thermally conductive sheets may be a stacked body obtained by alternately stacking a metal layer and a graphite layer or stacking a plurality of metal layers and/or a plurality of graphite layers in an arbitrary order with a plurality of adhesive layers above the graphite layers of the stacked body.

When a plurality of metal layers, a plurality of graphite layers, or a plurality of adhesive layers are used, the layers may be the same layer and may be different layers. In addition, it is desirable to use the same layer.

Also, thicknesses of the layers may be the same and different.

When a plurality of metal layers are used, it is desirable to use metal layers having roughened surfaces which are in contact with second adhesive layers 3b.

An order of stacking may be appropriately selected in accordance with desired applications and may be specifically selected in consideration of desired heat dissipation characteristics or the like. Furthermore, the number of stacked layers may be appropriately selected in accordance with desired applications and may be specifically selected in consideration of a size of a thermally conductive sheet, heat dissipation characteristics, or the like.

In thermally conductive sheets of the present invention, each of the thermally conductive sheets having an outermost layer serving as a metal layer is desirable in that a thermally conductive sheet with an excellent mechanical strength and processability is obtained.

Also, when thermally conductive sheets of the present invention are each used in an aspect illustrated in FIG. 5, a shape on a side which is not in contact with the second adhesive layer 3b of a layer farthest from a heating body 10 (the upper metal layer 2 in FIG. 1) may be set to have a shape in which a surface area is increased, for example, a pinholder shape or a bellows shape so that an area of a surface of the layer farthest from the heating body 10 which is in contact with the outside air is increased.

One of thermally conductive sheets of the present invention is preferably a stacked body 1 obtained by stacking the metal layers 2, the adhesive layers 3b, the graphite layer 4, the adhesive layers 3b, and the metal layers 2 in this order as shown in FIG. 5 in terms of excellent heat dissipation characteristics, mechanical strength, lightness, manufacturability, and the like.

Note that, for example, even when a thermally conductive sheet including the stacked body 1 shown in FIG. 5 is manufactured, particularly, when a user desires to manufacture a stacked body with a high bonding strength of the metal layers 2 via the graphite layer 4 in accordance with desired applications, two adhesive layers 3b may be directly in contact with each other. Examples of such a method include a method of using the graphite sheet 4b with the holes 5 provided as shown in FIG. 6 or the graphite sheet 4c with the slits 6 provided as shown in FIG. 7.

Also, two adhesive layers 3b are directly in contact with each other using a graphite layer 4 with a size smaller than sizes of metal layers 2 (vertical and horizontal lengths of a plate) so that a thermally conductive sheet with a high mechanical strength can be manufactured.

A shape, the number, and a size of holes or slits of a graphite sheet may be appropriately selected in terms of a mechanical strength, heat dissipation characteristics, and the like of a thermally conductive sheet.

When a graphite sheet with holes or slits provided therein is used, a thicker adhesive layers 3b are formed above metal layers 2 and a high temperature is set at the time of bonding as compared with, for example, when there are no hole or slits, so that an adhesive layer forming component flows into the holes or the slits and thus the holes or the slits can be filled with the adhesive layer forming component at the time of heating and pressing or the like. Furthermore, an adhesive layer of a portion above a metal layer corresponding to slits or holes of a graphite sheet may be formed to be thicker in advance using a dispenser or the like.

Also, thermally conductive sheets of the present invention may be constituted of a plurality of graphite sheets with no metal layers when a first adhesive layer 3a has been formed of a composition including a polyvinyl acetal resin. Since an adhesive layer has excellent adhesiveness, can be formed to be significantly thinner, and can have low thermal resistance if the first adhesive layer 3a is formed of the composition including the polyvinyl acetal resin, even when there is no metal layer, a thermally conductive sheet with excellent thermal conductivity between graphite sheets can be constituted.

For example, as shown in FIG. 8, there is a thickness of graphite from a layer including a plurality of graphite sheets 4a and 4a′ and a polyvinyl acetal resin serving as adhesive layers 3a and thus a thermally conductive sheet with a large area can be formed.

A thermally conductive sheet of the present invention may have a resin layer on one or both sides of surfaces opposite to surfaces which are in contact with outermost adhesive layers for the purpose of antioxidation or improvement in design. In other words, thermally conductive sheets of the present invention may each have resin layers as outermost layers thereof. The resin layer may be directly formed above a metal layer or a graphite layer and may be formed above a metal layer or a graphite layer via an appropriate adhesive layer.

### [Method of Manufacturing Thermally Conductive Sheet]

Thermally conductive sheets of the present invention can each be manufactured by, for example, applying a composition including a polyvinyl acetal resin to a metal plate or the like forming a metal layer or a graphite layer forming a graphite layer, disposing the metal plate or the like and the graphite layer to sandwich the composition after pre-drying the composition according to necessity, and heating the metal plate or the like and the graphite layer while being pressed. Furthermore, when a thermally conductive sheet is manufactured, it is desirable to apply the composition to both a metal plate or the like and a graphite layer in that a thermally conductive sheet with a high bonding strength between a metal layer and a graphite layer is obtained.

Before a composition including a polyvinyl acetal resin is applied, in the case of a metal layer, it is desirable to remove an oxidized layer of a surface with the composition applied thereto and perform degreasing cleaning on the surface, or in the case of a graphite layer, a surface thereof to which the composition is applied is subject to treatment for bonding easily using an oxygen plasma device, strong acid treatment, or the like, in that a thermally conductive sheet with a high bonding strength between a metal layer and a graphite layer can be obtained.

As a method of applying a composition including a polyvinyl acetal resin to a metal plate or the like or a graphite layer, although not particularly limited, it is desirable to use a wet coating method which can perform uniform coating of a composition. Among wet coating methods, when an adhesive layer with a thin film thickness, a spin coating method in which a simple and homogeneous film can be formed is desirable. When productivity is regarded as important, a gravure coating method, a die coating method, a bar coating method, a reverse coating method, a roll coating method, a slits coating method, a spray coating method, a kiss coating method, a reverse kiss coating method, an air knife coating method, a curtain coating method, a rod coating method, and the like are desirable.

In the case of pre-drying, although not particularly limited, when a composition including a solvent is used, the pre-drying may be appropriately selected in accordance with the solvent or the like. The pre-drying may be left the composition for about one to seven days at room temperature. In addition, it is desirable to heat the composition for about 1 to 10 minutes at a temperature of about 40 to 120° C. using a hot plate, a drying furnace, or the like.

Also, pre-drying may be performed in the atmosphere, may be performed under an inert gas atmosphere such as nitrogen gas and a rare gas if desired, and may be performed under a reduced pressure. Particularly, when drying is performed at a high temperature in a short time, the drying is preferably performed under an inert gas atmosphere.

A method of heating while applying a pressure may, but not particularly limited to, be appropriately selected in accordance with a component or the like forming an adhesive layer. In addition, a pressure is preferably 0.1 to 30 MPa, a heating temperature is preferably 200 to 250° C., and a heating and pressurizing time is preferably 1 minute to 1 hour. Furthermore, heating may be performed in the atmosphere, may be performed under an inert gas atmosphere such as nitrogen gas and a rare gas, and may be performed under a reduced pressure. Particularly, when heating is performed at a high temperature in a short time, the heating is preferably performed under an inert gas atmosphere or under a reduced pressure.

A thermally conductive sheet having resin layers on one or both sides of surfaces opposite to surfaces which are in contact with outermost adhesive layers may be manufactured by applying a paint including a resin to one or both sides of surfaces, which are opposite to surfaces contacting with adhesive layers, of metal layers or graphite layers serving as outermost layers of the thermally conductive sheet, drying the paint according to necessity, and curing the paint. Furthermore, the thermally conductive sheet can also be manufactured by forming a film made of a resin in advance, applying a composition which can form an adhesive layer on one or both sides of surfaces, which are opposite to surfaces contacting with adhesive layers, of metal layers or graphite layers serving as outermost layers of the thermally conductive sheet, drying the composition in advance according to necessity, bringing the film made of the resin into contact with the coated surfaces, applying a pressure according to necessity, performing heating, and the like.

A resin layer is not particularly limited as long as the resin layer includes a resin. In addition, examples of the resin include an acrylic resin, an epoxy resin, an alkyd resin, and a urethane resin which are widely used as a paint and a resin with a heat-resisting property is desirable among these.

Examples of a commercial product of a paint including the resin include a heat resistant paint (Okitsumo Inc.: trade name, a Heat Resistant Paint One Touch) and the like.

### [Application of Thermally Conductive Sheet]

Thermally conductive sheets of the present invention have adhesive layers with an excellent bonding strength between graphite sheets and an excellent bonding strength between a metal layer and a graphite layer and being thin. Thermally conductive sheets of the present invention have high thermal conductivity in a stacked direction and a direction which is substantially perpendicular to the stacked direction. Even when the entire thickness is thin, thermally conductive sheets of the present invention have heat dissipation characteristics which are equal to or greater than a thick heat dissipation plate in the related art. Furthermore, processability of cutting, drilling, die cutting and the like is excellent, an adhesive strength of a metal layer and a graphite layer is strong, and the metal layer and the graphite layer can be bent. For this reason, thermally conductive sheets of the present invention can be used for various applications and are suitably used for, particularly, electronic apparatuses and batteries.

Thermally conductive sheets of the present invention are also suitable as thermo-uniformity plates configured to prevent color unevenness of liquid crystal displays and organic electroluminescent lights.

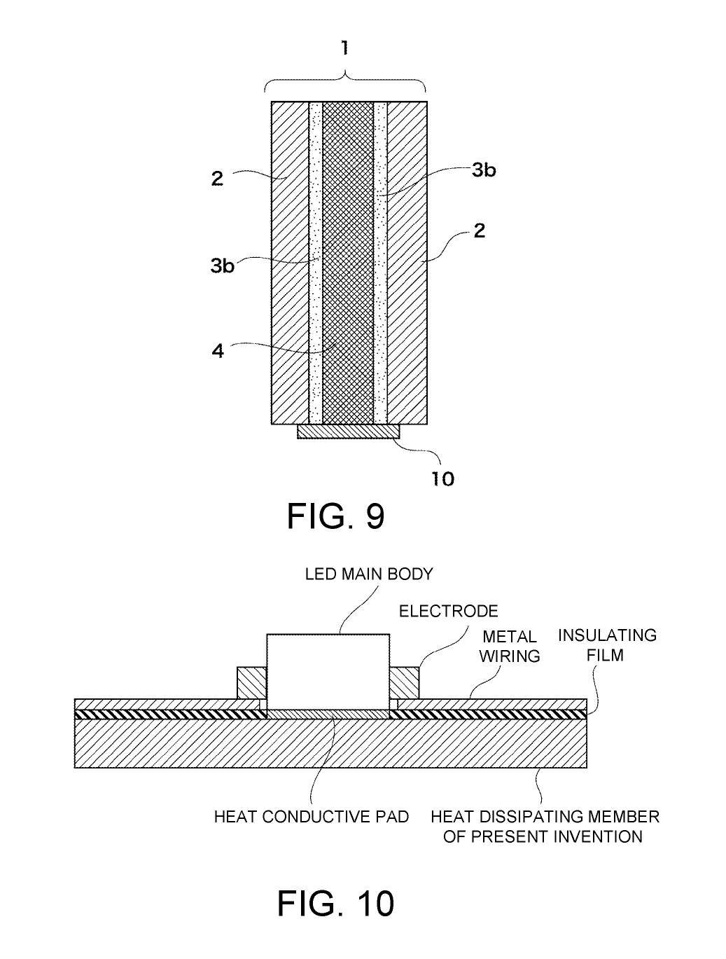

Application examples of thermally conductive sheets of the present invention to electronic device and the like, as shown in FIGS. 5 and 9 include a case in which a thermally conductive sheet 1 of the present invention is disposed to be in contact with a heating body 10 in an electronic device and used.

FIG. 5 is a schematic cross-section view illustrating an example of an electronic device in which a thermally conductive sheet 1 of the present invention is disposed such that a stacked direction of a stacked body is substantially perpendicular to a surface of a heating body 10. Furthermore, FIG. 9 is a schematic cross-section view illustrating an example of an electronic device in which a thermally conductive sheet 1 as shown in FIG. 5 is rotated by 90° and is disposed to be in contact with a heating body 10. The thermally conductive sheet 1 of the present invention is disposed as described above so that heat is diffused in a stacked direction of the thermally conductive sheet and in a direction which is substantially perpendicular to the stacked direction (a vertical direction) and thus a temperature rise near a heat source can be mitigated.

Note that, as shown in FIG. 9, when one of thermally conductive sheets of the present invention is disposed, a thermally conductive sheet cut in a stacked direction thereof may be used. Since heat generated from the heating body 10 can be rapidly dissipated (for example, transferred to a cooling device) when one of thermally conductive sheets of the present invention is disposed as shown in FIG. 9, a temperature rise of the heating body 10 can be effectively restrained.

### [Electronic Devices]

Examples of electronic devices include chips of application specific integrated circuits (ASICs) and the like used for image processing, a television receiver, an audio system, and the like, central processing units (CPUs) of personal computers, smartphones, and the like, light emitting diode (LED) lights, organic electroluminescence (EL) lights, and the like.

### [LED Lights]

LED lights will be described with reference to FIG. 10. FIG. 10 is a schematic cross-section view illustrating an example of an LED light in which a thermally conductive sheet of the present invention is disposed as a heat dissipating member on a rear surface of an LED main body to be in contact with via a heat conductive pad. Particularly, when an LED with the very high calorific value such as an ultra high brightness LED is used as the LED main body, applications of thermally conductive sheets of the present invention is effective.

In the LED main body configured to convert electric energy into light energy, heat is generated along with the turning-on and thus it is necessary to discharge the heat outside of the LED main body. The heat is transferred from the LED main body to the thermally conductive sheet of the present invention via the heat conductive pad and is dissipated through the thermally conductive sheet.

### [Batteries]

Examples of batteries include lithium ion secondary batteries, lithium ion capacitors, nickel hydrogen batteries, and the like used for vehicles, mobile phones, and the like.

Lithium ion capacitors may be modules in which a plurality of lithium ion capacitor cells are connected in series or in parallel.

In this case, thermally conductive sheets of the present invention may be disposed to be in contact with a part of an outer surface of the entire module or to cover the entire module or may be disposed to be in contact with a part of outer surfaces of lithium ion capacitor cells or to cover the cells.

A heat dissipating member needs high thermal conductivity performance. Furthermore, it has been seen that a heat dissipating member with higher thermal conductivity performance is obtained when an adhesive layer is thinner. Here, since an adhesive layer generally functions as a heat insulating layer, a sufficient bonding strength cannot be secured when a thickness is thin in an adhesive layer in the related art. However, in thermally conductive sheets of the present invention, a bonding strength of an adhesive layer can be sufficiently maintained and a thickness thereof can be thin. Particularly, thermally conductive sheets of the present invention are advantageous in that a bonding strength of an adhesive layer between graphite sheets can be sufficiently Maintained and a thickness thereof can be thin.

Also, thermally conductive sheets of the present invention can be used as heat dissipating components of electronic apparatuses, motors, and the like. Since electronic apparatuses and motors are used under vibrating conditions in some cases, it is desirable that a heat dissipating member serving as a stacked body has a sufficient bonding strength between layers. When the heat dissipating member does not have a sufficient bonding strength, there is a concern about separation of the heat dissipating member under use environments and impairment in performance of electronic apparatuses and motors. However, thermally conductive sheets of the present invention are advantageous in that a sufficient bonding strength is provided between layers.

### EXAMPLES

Hereinafter, the present invention will be described in detail using Examples. However, the present invention is not limited to the details disclosed in the following Examples.

Materials used for Examples of the present invention were as follows.

### <Adhesion Resin>

PVF-K: a polyvinyl formal resin, Vinylec K (trade name) manufactured by JNC Co., Ltd.
NeoFix10: an acrylic resin manufactured by NICHIEI KAKOH Co., Ltd.

### <Solvent>

Cyclopentanone: Wako 1st Grade manufactured by Wako Pure Chemical Industries Co., Ltd.

### <Graphite Sheet>

Graphite sheets (artificial graphite): SS-1500 (trade name) manufactured by GrafTECH International, thickness: 0.025 mm

(Thermal conductivity of a sheet in a surface direction: 1500 W/m·K)

### <Metal Plate>

Electrolytic copper foil with adhesive coating film: an electrolytic copper foil F2-WS (trade name) manufactured by FURUKAWA ELECTRIC Co., Ltd., thickness: 12 μm

### Example 1

First, an artificial graphite sheet was cut using a design knife to have sizes of (I) 55 mm×50 mm and (II) 50 mm×50 mm. 5 mm×50 mm in ends of the graphite sheet of (I) is set to a margin and a PVF-K solution (a solvent: cyclopentanone) with a solid concentration of 13% by weight was applied to the margin using a general painting brush (a small flat brush manufactured by TAMIYA, Inc.) such that a thickness after being dried had approximately 2 μm. A margin portion to which PVF-K was applied and an end portion of the graphite sheet to which PVF-K was not applied overlapped by a width of 5 mm before the solvent was dried (FIG. 6). The graphite sheet was bonded before the solvent was dried so that the graphite sheet was accurately joined through a paste and thus alignment or the like when being sandwiched by metal foils was facilitated. On the other hand, the overlapping was performed after the solvent was sufficiently dried using a hot plate or a drying furnace so that a heat dissipating member in which a gas was less generated from insides of the metal foils could be prepared. This could be appropriately selected depending on a temperature at which the heat dissipating member was used. In addition, when the heat dissipating member was used at a high temperature, a concern about gas generation from an inside of a pre-dried heat dissipating member is low.

Next, two copper foils with adhesive coating film (100 min×50 mm) sandwiched a graphite sheet bonded as described above while adhesive coating films thereof face an inside. Such a sample was sandwiched by a Kapton (registered trademark) film (a thickness: 100 μm) such that the copper foils were not stuck to a heat plate by PVF-K protruding from the copper foils, was left above a heat plate (220° C.) of a small-sized heating press (a MINI TEST PRESS-10 small-sized heating manual press: manufactured by TOYO SEIKI SEISAKU-SHO, Ltd.) for two minutes, and was pre-heated. After the pre-heating, the two copper foils and the graphite sheet were carefully subject to repeat pressurization and decompression several times such that a shift was not generated, degassing of the copper foils and the graphite sheets was performed, and the two copper foils and the graphite sheets were held for 5 minutes while being pressurized by 10 MPa. After that, the two copper foils and the graphite sheets were placed above a cooling plate (25° C.) of another press machine (MINI TEST PRESS-10 small-sized cooling manual press: manufactured by TOYO SEIKI SEISAKU-SHO, Ltd.) and were held for two minutes and cooled while being pressurized by 10 MPa. After the cooling, the pressure was released and a thermally conductive sheet (hereinafter referred to as a “heat dissipating member”) was obtained.

Note that a copper foil with adhesive coating film was prepared such that a thickness of PVF-K had approximately 2 μm using a method disclosed in Japanese Unexamined Patent Application Publication No. 2013-157599. A thickness of PVF-K was acquired by subtracting a thickness before the applying from a thickness after the applying using Digi-micro MF-501+Counter TC-101 manufactured by Nikon Co., Ltd.

Double-sided tapes (a NeoFix10 or a NeoFix5 manufactured by NICHIEI KAKOH Co., Ltd.) were attached to one sides of the obtained heat dissipating members, insulating tapes (GL-10B manufactured by NICHIEI KAKOH Co., Ltd.) were attached to rear surfaces of the heat dissipating members, and thus samples for heat dissipation characteristics evaluation were obtained.

### <Evaluation of Heat Dissipation Characteristics>

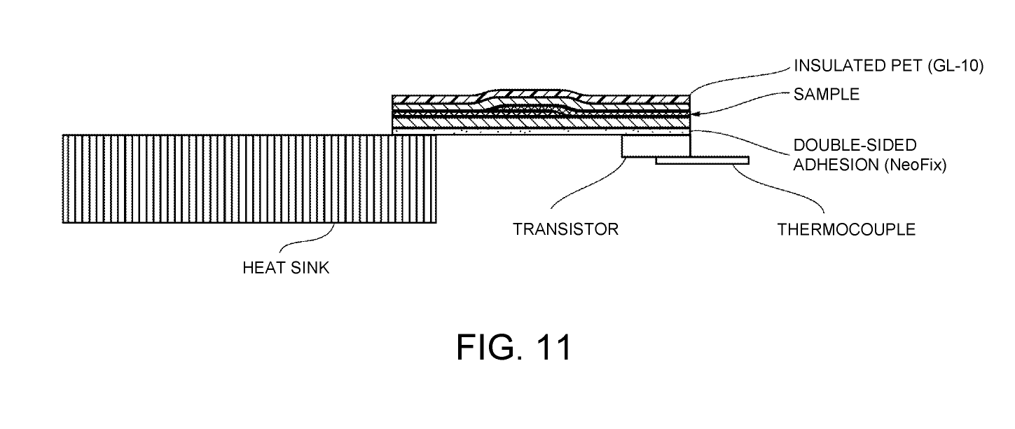

The samples for heat dissipation characteristics evaluation obtained in Example 1 were cut in a strip shape of 20 mm×80 mm. As shown in FIG. 11, transistors (2SD2013 manufactured by TOSHIBA Co., Ltd.) of T0220 packages were mounted on end portions of the cut heat dissipating members in a longitudinal direction thereof using the double-sided tapes. A K thermocouple (ST-50 manufactured by RKC INSTRUMENT Inc.) was mounted on rear surfaces of the transistors and temperatures thereof could be recorded on a personal computer using a data logger (a GL220 manufactured by GRAPHTEC Co.). Furthermore, a heat sink made of a metal was bonded to sides opposite to the heat dissipating members, to which the transistors were attached, in a longitudinal direction thereof. The transistors to which the thermocouple and the heat sink were mounted were left to stand on centers of a thermostatic bath which were set at 40° C., it was confirmed that temperatures of the transistors had been kept constant at 40° C., a voltage of 1.24 V was applied to the transistors using a direct current (DC) stabilized power supply, and changes in temperature of surfaces thereof were measured. Since transistors generate constant quantities of heat when receiving the same wattage, temperatures thereof are lower when heat dissipation effects of the mounted heat dissipating member are higher. In other words, it can be said that heat dissipation effects of a heat dissipating member, a temperature of a transistor of which is lower is higher.

### <Evaluation of Adhesiveness>

Bonding strengths of metal plates and graphite sheets of heat dissipating members obtained in Examples 1 to 12 and Comparative Example 1 were not easily acquired as a numerical value of a tensile load or the like when graphite sheets peel off because the graphite sheets had an attribute to be cleaved (to be separated inside a graphite layer). Therefore, metal portions of the heat dissipating members prepared in the examples were peeled off, states of inner surfaces of metal layers were visually observed, and evaluation was performed. When the entire surfaces of metal layers which were peeled off were covered by cleaved graphite, A is provided, when metal layers or adhesive layers slightly appear, B is provided, when metal layers or adhesive layers appear in ¼ or more of the entire surface, C is provided, and when little or no graphite remains, D is provided.

### Examples 2 to 8

Heat dissipating members were obtained as with Example 1 except a change in bonding widths and types of adhesive layers used to adhere graphite sheets as illustrated in Table 1 in Example 1.

### Examples 9 and 10

Heat dissipating members were obtained as with Example 1 except that three graphite sheets were used and bonding was performed as in FIG. 2.

### Comparative Example 1

A heat dissipating member was obtained as with Example 1 except that a graphite layer is formed of only one graphite sheet and bonding was performed as in FIG. 5.

### Example 11

A heat dissipating member was obtained as with Example 1 except that two graphite sheets were used and two graphite sheets and copper foils were stacked such that a gap was not generated between the two graphite sheets as in FIG. 3.

### Example 12

A heat dissipating member was obtained as with Example 1 except that two graphite sheets were used and the two graphite sheets and copper foils were stacked such that the two graphite sheets were separated 1 mm from each other as in FIG. 4.

### Reference Example 1

A heat dissipating member was obtained as with Example 1 except that two graphite sheets were used and the two graphite sheets and copper foils were stacked such the two graphite sheets were separated 5 mm from each other as in FIG. 4.

### Comparative Example 2

Graphite sheets themselves were used as a heat dissipating member without being stacked with respect to copper foils. In addition, a sample for heat dissipation characteristics evaluation was obtained by attaching heat conductive double-sided tapes (NeoFix10) to one sides of the graphite sheets and attaching and insulating tapes (NeoFix10BL) to rear surfaces thereof as with Example 1.

### Comparative Example 3

A heat dissipating member in which two graphite sheets were used and the two graphite sheets were separated 1 mm from each other without being stacked with respect to copper foils was obtained. In addition in addition, a sample for heat dissipation characteristics evaluation in which heat conductive double-sided tapes (NeoFix10) were attached to one sides of the graphite sheets and insulating tapes (GL-10B) were attached to rear surfaces thereof was obtained as with Example 1.

### [Review of Bonded Areas]

Comparing temperatures of transistors after 1800 seconds of samples of Examples 1 to 4 and 9 in which PVF-K was used as adhesive layers used to adhere graphite sheets, it was seen that the temperatures of the transistors decreased together with increases of bonded areas. It was considered that this was because the graphite sheets become thicker and thus an amount of heat flowing through a heat dissipating member increased.

Samples of Examples 5 to 8 and 10 in which NeoFix10 was used as adhesive layers used to adhere graphite sheets also have a similar trend.

### [Review of Adhesive Layer]

Comparing Examples 1 to 4 and 9 in which PVF-K was used as the adhesive layers used to adhere the graphite sheets with Examples 5 to 8 and 10 in which NeoFix10 was used as the adhesive layers used to adhere the graphite sheets, transistor temperatures of the samples in which PVF-K was used as the adhesive layers in all of the same bonded areas decreased. It was considered that this was because thermal conductivity in a thickness direction thereof was high due to thicknesses of PVF-K being thin to be 2 μm. Furthermore, there was a bonding strength equal or more than a cleavage of the graphite sheets in all of the heat dissipating members. When PVF-K was used as a type of resin of an adhesive layer, a bonding strength thereof could be maintained even when a thickness of the adhesive layer was thin. Thus, thermal conductivity of the obtained heat dissipating member in a stacked direction thereof was the highest when PVF-K was used as a type of resin of the adhesive layer. Therefore, it was seen that PVF-K was used for adhering graphite sheets and thus the entire thinner heat dissipating member with high performance can be prepared as compared with a case in which commercially available double-sided tapes was used. Furthermore, transistor temperatures of all of Examples 1 to 8 decreased as compared with Comparative Example 1 in which one graphite sheet is provided.

### [Review of Number of Used Graphite Sheets]

Comparing Examples 2 and 9 with Examples 6 and 10, there was no significant difference in transistor temperatures depending on the number of used graphite sheets. It was considered that heat dissipation characteristics depend on a bonded area rather than the number of used graphite sheets.

When Comparative Example 1 was compared with Example 11, there was no significant difference in transistor temperatures in the heat dissipating member formed of one graphite sheet and the heat dissipating member formed such that a gap was not provided between the graphite sheets. On the other hand, a transistor temperature of a heat dissipating member with two separated graphite sheets slightly increased as in Example 12. However, Example 11 and Example 12 were advantageous in that Example 11 and Example 12 had heat dissipation characteristics equivalent to Comparative Example 1 and could have an area larger than that of Comparative Example 1.

Comparing Comparative Example 2 and Comparative Example 3 which did not use a copper foil, a significant decrease of heat dissipation characteristics of Comparative Example 3 due to graphite sheets disposed to be separated was found. Since heat dissipation characteristics are lowered if a little shift occurs when graphite sheets are bonded, attention needs to be paid.

In addition, considering Reference Example 1, when a gap between graphite sheets is too large even in a structure as in FIG. 4, a transistor temperature increases. This is because a portion in which graphite sheets end and which is formed of only copper foils is a bottleneck in a flow of heat and effects of sandwiching the portion using copper foils are lowered if a distance of the portion is too long.

### <Review Regarding Application to Multilayer Graphite Sheet>

If was seen that thermal resistance between graphite sheets was low when the graphite sheets were bonded through a method of the present invention as compared with the related art. Thus, tests regarding whether it can be applied to adhesion of graphite sheets were performed.

### Example 13

A graphite sheet cut to 50 mm×50 mm was spin-coated with a PVF-K solution which was the same as that of Example 1 and thus an adhesive layer of 1 μm was formed. The graphite sheet with the adhesive layer and a graphite sheet with no an adhesive layer overlap such that the adhesive layers thereof were inside and were pressed under the same conditions as in the example. The obtained sample was sandwiched by an insulating layer and an adhesive layer as with Example 1 and was evaluated.

### Reference Example 2

For comparison, two graphite sheets cut to 50 mm×50 mm were carefully bonded using a double-sided adhesive tape (NeoFIX5) with a thickness of 5 μm such that air bubbles were not introduced. The obtained sample was sandwiched by an insulating layer and an adhesive layer as with Example 1 and evaluated.

Comparing Example 13 with Reference Example 2, a temperature of a transistor of Example 13 was slightly lower. Here, a thickness of a sample of Example 13 was 50 μm and a thickness of a sample of Reference Example 2 was 56 μm. Although PVF with a thickness of 1 μm was also used for an adhesive layer of the sample of Example 13, as results of observing using a operation electron microscope, PVF flowed into concave portions of the graphite sheets at the time of heating and pressurizing, convex portions thereof were substantially in contact with each other, and thus such a distance was 0 μm. On the other hand, when graphite sheets were bonded using a double-sided adhesive sheet, the graphite sheets were not thin due to a gap generated between concave portions of the graphite sheets and an adhesive layer or the like even when the graphite sheets were bonded. In recent years, since thinning of electronic devices is progressing, a product with a thickness as thin as 5 μm is desirable because a thickness of the product can be reduced, and the method of the present invention can be also applied to a thin graphite multilayer sheet with high performance.

TABLE 1
Measurement results

| | | | | | | | | | Heat dissipation |
|---|---|---|---|---|---|---|---|---|---|
| | | | | | | | | Adhesive | characteristics |
| | | | Adhesive layer | | Graphite sheet | | | property | Temperature of |
| | FIG. | Metal | | Thickness | Number of | Attachment | Attachment | Visual | transistor after 1800 |
| | No. | Type | Type | (μm) | using | width (mm) | area (%) | observation | seconds (° C.) |
| Example 1 | 1 | Copper | PVF-K | 2 | 2 | 5 | 6.25 | A | 78.4 |
| Example 2 | | Copper | PVF-K | 2 | 2 | 10 | 12.5 | A | 77.8 |
| Example 3 | | Copper | PVF-K | 2 | 2 | 20 | 25 | A | 76.1 |
| Example 4 | | Copper | PVF-K | 2 | 2 | 80 | 100 | A | 71.8 |
| Example 5 | | Copper | NeoFix10 | 10 | 2 | 5 | 6.25 | A | 78.9 |
| Example 6 | | Copper | NeoFix10 | 10 | 2 | 10 | 12.5 | A | 78.2 |
| Example 7 | | Copper | NeoFix10 | 10 | 2 | 20 | 25 | A | 77.0 |
| Example 8 | | Copper | NeoFix10 | 10 | 2 | 80 | 100 | A | 72.4 |
| Example 9 | 2 | Copper | PVF-K | 2 | 3 | 10 | 12.5 | A | 77.9 |
| Example 10 | | Copper | NeoFix110 | 10 | 3 | 10 | 12.5 | A | 78.1 |
| Comparative | 5 | Copper | | | 1 | | | A | 79.7 |
| example 1 | | | | | | | | | |
| Example 11 | 3 | Copper | | | 2 | 0 | 0 | A | 80.0 |
| Example 12 | 4 | Copper | | | 2 | | | A | 81.2 |
| Reference | 4 | Copper | | | 2 | | | A | 83.6 |
| example 1 | | | | | | | | | |
| Comparative | | | | | 1 | | | | 81.7 |
| example 2 | | | | | | | | | |
| Comparative | | | | | 2 | | | | 88.0 |
| example 3 | | | | | | | | | |
| Example 13 | | | PVF-K | 2 | 2 | 80 | 100 | A | 79.8 |
| Reference | | | NeoFix5 | 5 | 2 | 80 | 100 | A | 80.5 |
| example 2 | | | | | | | | | |

Publications, patent applications, and all literatures including patents cited in this specification are individually specifically represented, incorporated herein by reference, and incorporated herein by reference to the same extent as that which the overall content of which is described herein.

It is interpreted that nouns and similar directives used in connection with the description of the present invention (in connection with, particularly, the following claims) are both singular or plural unless they are particularly pointed in the present specification or are clearly inconsistent with the context. The terms “comprise,” “has,” “include,” and “contain” are interpreted as the open end term (that is, it means the expression “including but not limited to”) unless otherwise noted. Formal statements of ranges of numerical values in the present specification are merely intended to play a role as abbreviation used to simply mention values falling within the ranges unless they are not particularly pointed in the present specification and the values are incorporated into the specification as listed in the present specification. All methods described in the present specification can be performed in any appropriate order unless they are particularly pointed in the present specification or are clearly inconsistent with the context. Any examples or exemplary expressions (for example, “and the like”) used in the present specification are intended to merely better describe the present invention unless not particularly asserted and is not intended to limit the scope of the present invention. Any expressions in the specification are not interpreted as indicating elements, which are not described the claims, which are essential to the implement of the present invention.

The present specification includes the best modes known to the inventors for carrying out the present invention and describes the preferred embodiments of the present invention. Variations of these preferred embodiments will become apparent when those of ordinary skill in the art read the above description. The inventors anticipates that the skilled person appropriately applies such variations and the present invention is intended to be carried out using methods other than the methods specifically described in the present specification. Therefore, the present invention includes all changes and equivalents of the details described in the claims appended in the present specification as permitted in an applicable law. In addition, any combinations of the above-described elements in all variations are also included unless they are particularly pointed in the present specification or are clearly inconsistent with the context.

### REFERENCE SIGNS LIST

1 thermally conductive sheet
2 metal layer
3a first adhesive layer
3b second adhesive layer
4 graphite layer
4a graphite sheet
4a′ graphite sheet
4a″ graphite sheet
4b graphite sheet
4c graphite sheet
5 hole
6 slit
10 heating body

1. A thermally conductive sheet constituted of a plurality of graphite sheets, the thermally conductive sheet comprising:
a first graphite sheet;
a second graphite sheet that is any of a second graphite sheet disposed to entirely overlap the first graphite sheet, a second graphite sheet disposed to partially overlap and to be shifted from the first graphite sheet, and a second graphite sheet disposed such that there is an interval of less than 5 mm between the second graphite sheet and the first graphite sheet;
a first adhesive layer configured to adhere facing surfaces of the first graphite sheet and the second graphite sheet which are disposed;
metal layers stacked to sandwich the first graphite sheet and the second graphite sheet which are disposed from the top and bottom; and
second adhesive layers configured to adhere facing surfaces of the first graphite sheet, the second graphite sheet, and the metal layers which are disposed.

2. The thermally conductive sheet according to claim 1, wherein the first adhesive layer includes a polyvinyl acetal resin or an acrylic resin, and
the second adhesive layer includes a polyvinyl acetal resin.

3. The thermally conductive sheet according to claim 1, wherein the first adhesive layer includes a polyvinyl acetal resin, and
the second adhesive layer includes an acrylic resin.

4. The thermally conductive sheet according to claim 1, further comprising:
a third graphite sheet disposed to partially overlap the first graphite sheet and the second graphite sheet which are disposed to have the interval of less than 5 mm therefrom,
wherein facing surfaces of the first graphite sheet and the third graphite sheet are adhered with the first adhesive layer and facing surfaces of the second graphite sheet and the third graphite sheet with the first adhesive layer.

5. The thermally conductive sheet according to claim 2, wherein the polyvinyl acetal resin includes the following constituent units A, B, and C, and
in the constituent unit A, R is independently hydrogen or an alkyl group with 1 to 5 carbon atoms.

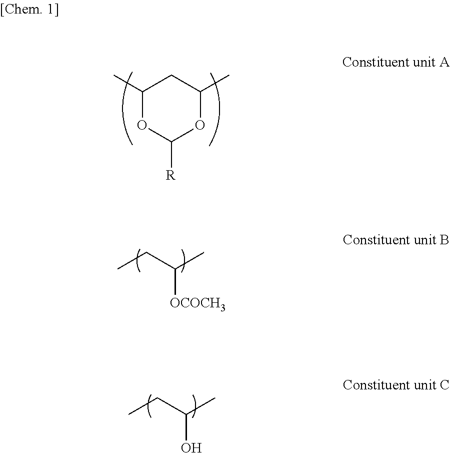

6. The thermally conductive sheet according to claim 5, wherein the polyvinyl acetal resin further includes the following constituent unit D, and
in the constituent unit D, R¹ is independently hydrogen or an alkyl group with 1 to 5 carbon atoms.

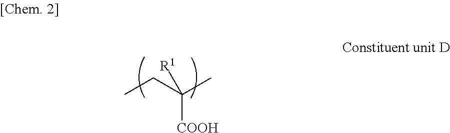

7. The thermally conductive sheet according to claim 1, wherein the adhesive layer further includes a thermally conductive filler.

8. The thermally conductive sheet according to claim 1, wherein thicknesses of the first graphite sheet and the second graphite sheet are 10 to 300 μm.

9. The thermally conductive sheet according to claim 1, wherein a thickness of the metal layers is 0.01 to 10 times the thickness of the first graphite sheet or the second graphite sheet.

10. The thermally conductive sheet according to claim 1, wherein the metal layer includes at least one type of metal selected from the group consisting of silver, copper, aluminum, nickel, magnesium, titanium, and an alloy containing at least one metal of these.

11. An electronic apparatus comprising:
the thermally conductive sheet according to claim 1; and
an electronic device having a heating body,
wherein the thermally conductive sheet is disposed in the electronic device to be in contact with the heating body.

12. A thermally conductive sheet constituted of a plurality of graphite sheets, the thermally conductive sheet comprising:
a first graphite sheet;
a second graphite sheet that is any of a second graphite sheet disposed to entirely overlap the first graphite sheet, a second graphite sheet disposed to partially overlap and to be shifted from the first graphite sheet, and a second graphite sheet disposed such that there is an interval of less than 5 mm between the second graphite sheet and the first graphite sheet; and
a first adhesive layer configured to adhere facing surfaces of the first graphite sheet and the second graphite sheet which are disposed,
wherein the first adhesive layer includes a polyvinyl acetal resin.
